(19) United States
(12) Patent Application Publication
(10) Pub. No.: US 2007/0180344 A1
(43) Pub. Date: Aug. 2, 2007

(54) Techniques for low density parity check for forward error correction in high-data rate transmission

(76) Inventors: Eric A. Jacobsen, Scottsdale, AZ (US); Bo Xia, Cupertino, CA (US)

Correspondence Address: KACVINSKY LLC;C/O INTELLEVATE, P.O. BOX 52050, MINNEAPOLIS, MN, 55402, US

(21) Appl. No.: 11/344,036

(22) Filed: Jan. 31, 2006

(51) Int. Cl. H03M 13/00

(52) U.S. Cl. 714/752

(57) ABSTRACT

A system, apparatus, and method includes a decoder to decode information including a low density parity check (LDPC) codeword received at a node using entries defined in a parity check base matrix. Other embodiments are described and claimed. The system further includes an antenna.

### BACKGROUND

Computers, including mobile and fixed wireless devices, communicate and exchange data and other types of information such as voice and multimedia communications (e.g., video, sound, data) over local and distributed wired and wireless communication networks. Mobile computers may communicate with each other and other computers connected to Wide Area Networks (WAN) such as Internet using Wireless Local Area Networks (WLAN) communication systems. Most communications networks are designed to convey multiple communications simultaneously over each individual communication path, for example, a radio frequency (RF) channel or physical connection, using some form of multicarrier communication. Multicarrier communications may be described as a communications technique in which multiple carriers or subcarriers are used to communicate information. In recent years, an increasing demand has arisen for efficient and reliable digital data transfers which assure correct data transmissions at as great a data rate as possible.

Wireless channels, however, are often plagued by noise and/or interference effects that can compromise the quality of the communication flowing there through. One strategy for addressing these concerns involves the use of a forward error correction code (FEC) to encode data before it is transmitted. The FEC code adds redundant information to the original data that allows errors in transmission to be corrected after signal reception. Error correction codes are an essential component of many wireless standards. Structures and techniques are needed for reliably and efficiently implementing forward error correction in wireless systems. FEC codes have been used in some communications systems for this purpose.

Codes are essentially digital data sequences derived from message sequences and used to convey message information. In FEC, information may be encoded to provide the abilities of detection and/or correction of errors occurring during transmission in a noisy channel. The receiver in a communication system can recover all the information in the codewords by itself and thus coding lends advantages to high speed communication systems and/or those requiring synchronous communications.

Telecommunications systems apply low-density parity-check (LDPC) codes to provide error correction capability. These LDPC codes are being applied to a variety of telecommunications standards, including, for example, Digital Video Broadcast Via Satellite (DVB-S2), the Institute of Electrical and Electronics Engineers (IEEE) 802.11n Wireless LAN proposal, the IEEE 802.16e Wireless Metropolitan Area Network (MAN) proposal, among others. In many telecommunications error correction applications, a LDPC decoder may be used to decode a variety of codes in a single receiver.

LDPC codes are a type of FEC block codes which are constructed using a number of simple parity-check relationships shared between the bits in a codeword. An LDPC code (n, k) where n is the codeword length and k is the information length, is usually represented by a sparse parity-check matrix H with dimension n*(n−k). The parity check matrix is used as a basis for encoding and decoding LDPC codewords. LDPC codes are well known for their excellent performance in communications systems but due to their block nature, they have thus far not been flexible enough for systems where either information length or codeword length (or both) is variable.

### BRIEF DESCRIPTION OF THE DRAWINGS

FIG. 1 illustrates one embodiment of a system.

FIG. 2 illustrates one embodiment of a component.

FIG. 3 illustrates one embodiment of a parity check matrix.

FIG. 4 illustrates one embodiment of a bipartite graph associated with the parity check matrix shown in FIG. 3.

FIG. 5 illustrates one embodiment of a parity check base matrix H₁.

FIG. 6 illustrates one embodiment of a parity check base matrix H₂.

FIG. 7 illustrates one embodiment of a parity check base matrix H₃.

FIG. 8 illustrates one embodiment of a logic flow.

### DETAILED DESCRIPTION

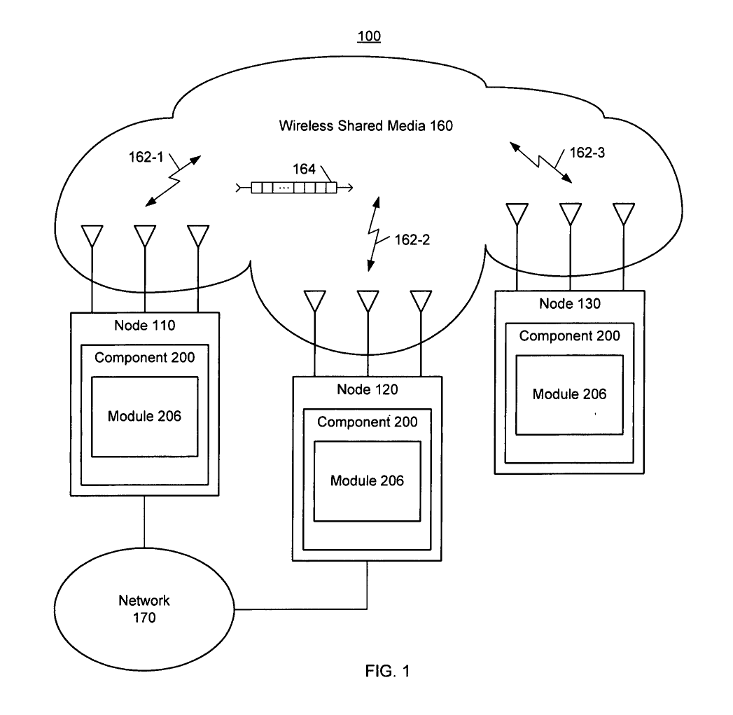

FIG. 1 illustrates one embodiment of a system. FIG. 1 may illustrate a block diagram of a system 100, for example. System 100 may be a distributed system. System 100 may comprise, for example, a communication system having multiple nodes. A node may comprise any physical or logical entity having a unique address in system 100. Examples of a node may include, but are not necessarily limited to, a computer, server, workstation, laptop, ultra-laptop, handheld computer, telephone, cellular telephone, personal digital assistant (PDA), router, switch, bridge, hub, gateway, wireless access point, and so forth. The unique address may comprise, for example, a network address such as an Internet Protocol (IP) address, a device address such as a MAC address, and so forth. The embodiments are not limited in this context.

The nodes of system 100 may be arranged to communicate different types of information, such as media information and control information. Media information may refer to any data representing content meant for a user, such as voice information, video information, audio information, text information, numerical information, alphanumeric symbols, graphics, images, and combinations thereof, for example. Control information may refer to any data representing commands, instructions or control words meant for an automated system. For example, control information may be used to route media information through a system or instruct a node to process the media information in a predetermined manner.

The nodes of system 100 may communicate media and control information in accordance with one or more protocols. A protocol may comprise a set of predefined rules or instructions to control how the nodes communicate information between each other. The protocol may be defined by one or more protocol standards as promulgated by a standards organization, such as the Internet Engineering Task Force (IETF), International Telecommunications Union (ITU), the IEEE, and so forth. For example, system 100 may operate in accordance with various WLAN protocols, such as the IEEE 802.11 series of protocols, including the IEEE 802.11a, 802.11b, 802.11e, 802.11g, 802.11n, and so forth. In another example, system 100 may operate in accordance with various WMAN mobile broadband wireless access (MBWA) protocols, such as a protocol from the IEEE 802.16 or 802.20 series of protocols.

Referring again to FIG. 1, system 100 may comprise a wireless communication system. In one embodiment, system 100 may comprise a WLAN or WMAN system operating in accordance with the IEEE 802.11, 802.16 or 802.20 series of standard protocols. In one embodiment, for example, system 100 may comprise a WLAN system operating with a number of high throughput (HT) wireless devices arranged to operate in accordance with one or more of the IEEE-802.11n proposed standards. The embodiments are not limited in this context.

In one embodiment, system 100 may include one or more wireless communication devices, such as nodes 110, 120, 130. Nodes 110, 120, 130 all may be arranged to communicate information signals using one or more wireless transmitters/receivers (“transceivers”) or radios, which may involve the use of radio frequency communication via IEEE 802.11 Frequency Hopping Spread Spectrum (FHSS) or Direct Sequence Spread Spectrum (DSSS) schemes. Nodes 110, 120, 130 may communicate using the radios over wireless shared media 160 via multiple channels 162 or links established therein such as channels 162-1, 162-2, 162-3. For example, the radios may be arranged to operate using the 2.45 Gigahertz (GHz) Industrial, Scientific, and Medical (ISM) band of wireless shared media 160. Other operating bands may be used as well. Information signals may include any type of signal encoded with information, such as media and/or control information. Although FIG. 1 is shown with a limited number of nodes in a certain topology, it may be appreciated that system 100 may include additional or fewer nodes in any type of topology as desired for a given implementation. The embodiments are not limited in this context.

In one embodiment, system 100 may include nodes 110, 120. Nodes 110, 120 may comprise fixed devices having wireless capabilities. A fixed device may comprise a generalized equipment set providing connectivity, management, and control of another device, such as mobile devices. Examples for nodes 110, 120 may include a wireless access point (AP), base station or node B, router, switch, hub, gateway, and so forth. In one embodiment, for example, nodes 110, 120 may comprise access points for a WLAN system. Although some embodiments may be described with nodes 110, 120 implemented as an AP by way of example, it may be appreciated that other embodiments may be implemented using other wireless devices as well.

In one embodiment, AP nodes 110, 120 also may provide access to a network 170 via wired communications media. Network 170 may comprise, for example, a packet network such as Internet, a corporate or enterprise network, a voice network such as the Public Switched Telephone Network (PSTN), among other WANs, for example. The embodiments are not limited in this context.

In one embodiment, system 100 may include node 130. Node 130 may comprise, for example, a mobile device or a fixed device having wireless capabilities. A mobile device may comprise a generalized equipment set providing connectivity to other wireless devices, such as other mobile devices or fixed devices. Examples for node 130 may include a computer, server, workstation, notebook computer, handheld computer, telephone, cellular telephone, personal digital assistant (PDA), combination cellular telephone and PDA, and so forth. In one embodiment, for example, node 130 may comprise a mobile device, such as a mobile station (STA) for a WLAN. In a WLAN implementation, the combination of an AP and associated stations may be referred to as a Basic Service Set (BSS). Although some embodiments may be described with STA node 130 implemented as a mobile station for a WLAN by way of example, it may be appreciated that other embodiments may be implemented using other wireless devices as well. For example, node 130 also may be implemented as a fixed device such as a computer, a mobile subscriber station (MSS) for a WMAN, and so forth. The embodiments are not limited in this context.

Nodes 110, 120, 130 may have one or more wireless transceivers and wireless antennas. In one embodiment, for example, nodes 110, 120, 130 may each have multiple transceivers and multiple antennas. The use of multiple antennas may be used to provide a spatial division multiple access (SDMA) system or a multiple-input multiple-output (MIMO) system in accordance with one or more of the IEEE 802.11n proposed standards, for example. Multiple transmitting antennas may be used to increase data rates in a channel or to increase range and reliability of data transmitted in a channel without an increase in data rates. Data rates also may be increased by using multiple antennas to transmit data in multiple channels at the same time. Multiple receiving antennas may be used to efficiently recover transmitted data. The embodiments are not limited in this context.

In general operation, the nodes of system 100 may operate in multiple operating modes. For example, nodes 110, 120, 130 may operate in at least one of the following operating modes: a single-input-single-output (SISO) mode, a multiple-input-single-output (MISO) mode, a single-input-multiple-output (SIMO) mode, and/or in a MIMO mode. In a SISO operating mode, a single transmitter and a single receiver may be used to communicate information signals over a wireless shared medium 160. In a MISO operating mode, two or more transmitters may transmit information signals over wireless shared media 160, and information signals may be received from wireless shared media 160 by a single receiver of a MIMO system. In a SIMO operating mode, one transmitter and two or more receivers may be used to communicate information signals over wireless shared media. In a MIMO operating mode, two or more transmitters and two or more receivers may be used to communicate information signals over wireless shared media 160. A channel 162, link, or connection may be formed using one or more frequency bands of wireless shared medium 160 for transmitting and receiving packets 164. The embodiments are not limited in this context.

In system 100, STA node 130 may communicate with various AP, such as AP node 110, 120. To communicate with AP node 110 or AP node 120, STA node 130 may first need to associate with a given AP. Once STA node 130 is associated with an AP, STA node 130 may need to select a data rate for packets with media and control information over wireless shared media 160. STA node 130 may select a data rate once per association, or may periodically select data rates to adapt to transmitting conditions of wireless shared media 160. Adapting data rates to transmitting conditions may sometimes be referred to as rate adaptation operations.

A WLAN such as system 100 may operate at a number of different data rates or data throughputs. For example, original 802.11 systems using DSSS radios offered only two physical data rates of 1 Megabits per second (Mbps) or 2 Mbps. Current WLAN systems operating in accordance with a number of orthogonal frequency division multiplexing (OFDM) techniques, however, may support a wide range of data rates of up to 54 Mbps or more in the 2.4 GHz region. Other potentially higher data rates and transmit modes may be available as well. Examples of such WLAN systems may include 802.11g and 802.11n systems.

Accordingly, in one embodiment, system 100 may comprise component 200 in associated nodes 110, 120, 130 to implement techniques to provide communications devices that support multiple standards in order to improve overall performance in nodes 110, 120, 130, and to increase overall system 100 performance. Component 200 may comprise a module 206 depending on the particular embodiment thereof. In one embodiment, module 206 may comprise an LDPC encoder/decoder to encode/decode a variety of codes in a single transceiver (e.g., or a transmitter and receiver). The LDPC encoder/decoder may be implemented either as a Digital Signal Processor (DSP) or an Application Specific Integrated Circuit (ASIC). Embodiments of module 206 comprising a LDPC encoder/decoder implemented as a DSP may provide a flexible solution although the speed that it can operate at may be limited by power constraints, for example. Embodiments of module 206 comprising a encoder/decoder implemented as an ASIC may operate at higher speeds although it may not provide the same flexibility as a DSP implementation because it is “hard-wired” and, accordingly, may be difficult to reconfigure once it has been built. Embodiments of module 206 comprising a LDPC encoder/decoder may be programmed for decoding multiple codes such as LDPC or other FEC codes by downloading new programming into the address generator modules of the decoder. Further, a LDPC encoder/decoder may be programmed for new protocols, thus enabling it to be more widely used across telecommunications products with less time-to-market. Moreover, embodiments of a LDPC encoder/decoder reduces the complex routing between check and symbol nodes, thus simplifying its implementation.

In various embodiments, system 100 may be illustrated and described as comprising several separate functional elements, such as modules and/or blocks. Although certain modules and/or blocks may be described by way of example, it can be appreciated that a additional or fewer number of modules and/or blocks may be used and still fall within the scope of the embodiments. Further, although various embodiments may be described in terms of modules and/or blocks to facilitate description, such modules and/or blocks may be implemented by one or more hardware components (e.g., processors, DSPs, PLDs, ASICs, circuits, registers), software components (e.g., programs, subroutines, logic) and/or combination thereof.

In various embodiments, system 100 may comprise multiple modules connected by one or more communications media. Communications media generally may comprise any medium capable of carrying information signals. For example, communications media may comprise wired communications media, wireless communications media, or any combination of both, as desired for a given implementation. Examples of wired communications media may include a wire, cable, printed circuit board (PCB), backplane, semiconductor material, twisted-pair wire, co-axial cable, fiber optics, and so forth. An example of a wireless communications media may include portions of a wireless spectrum, such as the radio-frequency (RF) spectrum. The embodiments are not limited in this context.

The modules may comprise, or may be implemented as, one or more systems, sub-systems, devices, components, circuits, logic, programs, or any combination thereof, as desired for a given set of design or performance constraints. For example, the modules may comprise electronic elements fabricated on a substrate. In various implementations, the electronic elements may be fabricated using silicon-based IC processes such as complementary metal oxide semiconductor (CMOS), bipolar, and bipolar CMOS (BiCMOS) processes, for example. The embodiments are not limited in this context.

In one embodiment, nodes 110, 120, 130 communicate over wireless links. The wireless links between wireless nodes 110, 120, 130 may experience noise and/or various interference effects that can compromise communication quality. To overcome these limitations, a FEC code may be used. That is, a FEC coder may be provided within a transmitting device, e.g., module 206 of component 200, to encode data before it is wirelessly transmitted. When the signal is received, a FEC decoder within a receiving device, e.g., module 206 of component 200, may be used to decode the signal. The FEC decoder is capable of detecting and correcting one or more errors in the received data. In this manner, errors caused by noise and/or interference effects in the channel 162 may be overcome. In one embodiment, a LDPC code may be used as the FEC code within a wireless device such as nodes 110, 120, 130.

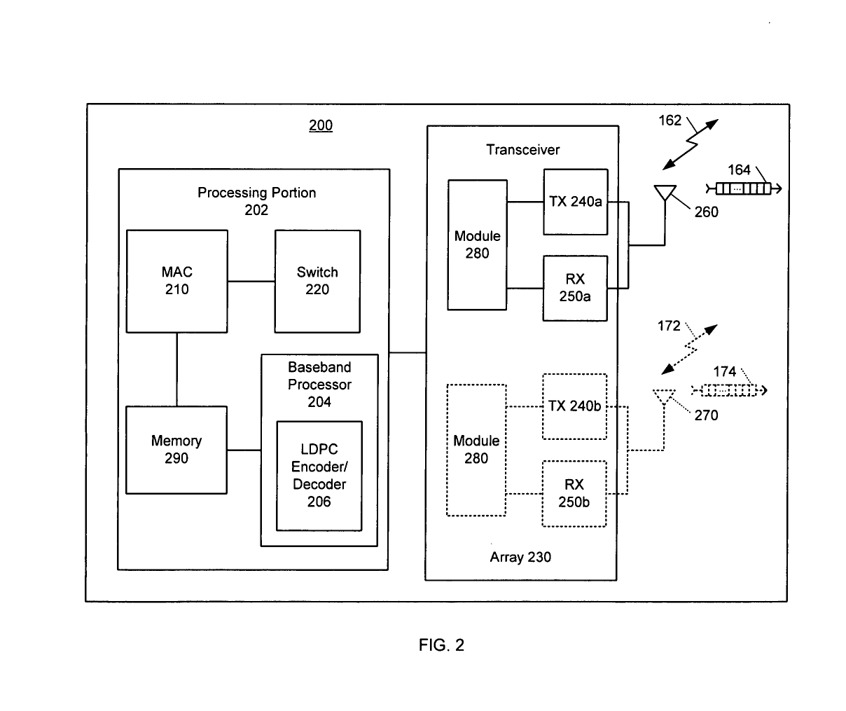

FIG. 2 illustrates one embodiment of a component. FIG. 2 may illustrate a block diagram for component 200 of system 100, for example. Component 200 may be implemented as part of nodes 110, 120 or 130 as described with reference to FIG. 1. As shown in FIG. 2, component 200 may comprise a processing portion 202 and a transceiver array 230 portion. Processing portion 202 may comprise multiple elements, such as baseband processor 204 comprising a LDPC encoder/decoder 206, processor 210, switch (SW) 220, and memory 290. Some elements may be implemented using, for example, one or more circuits, components, registers, processors, software subroutines, or any combination thereof. Although FIG. 2 shows a limited number of elements, it can be appreciated that additional or fewer elements may be used in component 200 as desired for a given implementation. The embodiments are not limited in this context.

In one embodiment, component 200 may include transceiver array 230. Transceiver array 230 may comprise multiple transmitter 240a, b and receiver 250a, b pairs. In one embodiment, each transmitter 240a, b and receiver 250a, b pair may comprise module 280 based on the specific embodiments thereof. In one embodiment, module 280 may be an amplifier. Transceiver array 230 may be implemented as, for example, a MIMO system. MIMO system 230 may include two transmitters 240a and 240b, and two receivers 250a and 250b. Although MIMO system 230 is shown with a limited number of transmitters and receivers, it may be appreciated that MIMO system 230 may include any desired number of transmitters and receivers. The embodiments are not limited in this context.

In one embodiment, transmitters 240a-b and receivers 250a-b of MIMO system 230 may be implemented as OFDM transmitters and receivers. Transmitters 240a-b and receivers 250a-b may communicate packets 164, 174, respectively, with other wireless devices over channels 162, 172, respectively. For example, when implemented as part of AP node 110 or AP node 120, transmitters 240a-b and receivers 250a-b may communicate packets 164, 174 with STA node 130. When implemented as part of STA node 130, transmitters 240a-b and receivers 250a-b may communicate packets 164, 174 with AP node 110 or AP node 120. The packets may be modulated in accordance with a number of modulation schemes, to include Binary Phase Shift Keying (BPSK), Quadrature Phase-Shift Keying (QPSK), Quadrature Amplitude Modulation (QAM), 16-QAM, 64-QAM, and so forth. The embodiments are not limited in this context.

In one embodiment, transmitter 240a and receiver 250a may be operably coupled to an antenna 260, and transmitter 240b and receiver 250b may be operably coupled to antenna 270. Examples for antenna 260 and/or antenna 270 may include an internal antenna, an omni-directional antenna, a monopole antenna, a dipole antenna, an end fed antenna, a circularly polarized antenna, a micro-strip antenna, a diversity antenna, a dual antenna, an antenna array, a helical antenna, and so forth. In one embodiment, system 100 may be implemented as a MIMO based WLAN comprising multiple antennas to increase throughput and may trade off increased range for increased throughput. MIMO-based technologies may be applied to other wireless technologies as well. Although in one embodiment system 100 may be implemented as a WLAN in accordance with 802.11a/b/g/n protocols for wireless access in an enterprise, other embodiments in use in the enterprise may include reconfigurable radio technologies and/or multiple radios (e.g., multiple transceivers, transmitters, and/or receivers), for example. The embodiments are not limited in this context.

Processing portion 202 may be configured to perform digital communication functions such as a medium access control 210 and/or baseband processing 204. In one example implementation, an LDPC encoder/decoder 206 configured to perform an encoding method is integrated, along with an optional digital demodulator (not separately shown), as part of digital baseband processor 204. The embodiments are however not limited in this respect. Additional elements, such as one or more analog to digital converters (ADC), digital to analog converters (DAC), a memory controller, a digital modulator and/or other associated elements, may also be included as part of component 200.

In one embodiment, component 200 may include a processor 210. Processor 210 may be implemented as a general purpose processor. For example, processor 210 may comprise a general purpose processor made by Intel® Corporation, Santa Clara, Calif. Processor 210 also may comprise a dedicated processor, such as a controller, microcontroller, embedded processor, a digital signal processor (DSP), a network processor, an input/output (I/O) processor, a media processor, and so forth. The embodiments are not limited in this context.

In one embodiment, component 200 may include a memory 290. Memory 290 may comprise any machine-readable or computer-readable media capable of storing data, including both volatile and non-volatile memory. For example, the memory may comprise read-only memory (ROM), random-access memory (RAM), dynamic RAM (DRAM), Double-Data-Rate DRAM (DDRAM), synchronous DRAM (SDRAM), static RAM (SRAM), programmable ROM (PROM), erasable programmable ROM (EPROM), electrically erasable programmable ROM (EEPROM), flash memory, polymer memory such as ferroelectric polymer memory, ovonic memory, phase change or ferroelectric memory, silicon-oxide-nitride-oxide-silicon (SONOS) memory, magnetic or optical cards, or any other type of media suitable for storing information. The embodiments are not limited in this context.

In one embodiment, nodes 110, 120, 130 of system 100 may operate in accordance with one or more of the IEEE 802.11 series of specifications. A wireless device operating in accordance with an IEEE 802.11 specification may require the implementation of at least two layers. One layer is the 802.11 MAC layer (i.e., OSI Data/Link Layer 2). In general, the MAC layer manages and maintains communications between 802.11 devices by coordinating access to a shared radio channel and utilizing protocols to enhance communications over wireless shared media 160. For example, the MAC layer may perform such operations as scanning for 802.11 devices, authenticating 802.11 devices, associating an AP with a STA, performing security techniques such as wireless encryption protocol (WEP), request to send (RTS) and clear to send (CTS) operations to access wireless shared media 160, power saving operations, fragmentation operations, and so forth. Another layer is the 802.11 PHY layer (i.e., OSI Physical Layer 1). The PHY layer may perform the operations of carrier sensing, transmission, and receiving of 802.11 frames. For example, the PHY layer may integrate operations such as modulation, demodulation, encoding, decoding, analog-to-digital conversion, digital-to-analog conversion, filtering, and so forth. The PHY layer may be implemented using dedicated hardware. The MAC layer, however, may be implemented using a combination of dedicated hardware and dedicated software.

In one embodiment, processor 210 may be arranged to perform MAC layer operations. For example, processor 210 may be implemented as a media access control (MAC) processor. MAC 210 may be arranged to perform MAC layer processing operations. In addition, MAC 210 may be arranged to select a data rate to communicate media and control information between wireless devices over wireless shared media 160 in accordance with one or more WLAN protocols, such as one or more of the IEEE 802.11n proposed standards, for example. The embodiments, however, are not limited in this context.

When implemented in a node of system 100, component 200 may be arranged to communicate information in wireless shared media 160 between the various nodes, such as AP node 110, AP node 120, and STA node 130. The information may be communicated in the form of packets 164, 174 over channels 162, 172 established, with each packet 164, 174 comprising media information and/or control information. The media and/or control information may be represented using, for example, multiple OFDM symbols. Packets 164, 174 may be part of a frame, which in this context may refer to any discrete set of information, including a unit, packet, cell, segment, fragment, and so forth. The frame may be of any size suitable for a given implementation. Typical WLAN protocols use frames of several hundred bytes, and an 802.11 frame may have a length of up to 1518 bytes or more, for example. In one embodiment, nodes of system 100 and component 200 may be arranged to communicate information over wireless shared media 160 between the various nodes, such as AP node 110, AP node 120, and STA node 130. Although embodiments describe communication of information in the form of packets 164, 174 over wireless channels 162, 172, the embodiments are not limited in this context.

When implemented as part of STA node 130, MAC 210 may be arranged to associate with an AP. For example, MAC 210 may passively scan for access points, such as AP nodes 110, 120. AP nodes 110, 120 may periodically broadcast a beacon. The beacon may contain information about the access point including a service set identifier (SSID), supported data rates, and so forth. MAC 210 may use this information and the received signal strength for each beacon to compare AP and decide upon which one to use. Alternatively, MAC 210 may perform active scanning by broadcasting a probe frame, and receiving probe responses from AP nodes 110, 120. Once an AP has been selected, MAC 210 may perform authentication operations to prove the identity of the selected AP. Authentication operations may be accomplished using authentication request frames and authentication response frames. Once authenticated, STA node 130 associates with the selected AP before sending packets. Association may assist in synchronizing STA node 130 and the AP with certain information, such as supported data rates. Association operations may be accomplished using association request frames and association response frames containing elements such as SSID and supported data rates. Once association operations are completed, STA node 130 and AP node 110 can send packets to each other, although the embodiments are not limited in this regard.

In some embodiments, MAC 210 also may be arranged to select a data rate to communicate packets based on current channel 162, 172 conditions for wireless shared media 160. For example, assume STA node 130 associates with a peer, such as an AP or other wireless device (e.g., AP node 110). STA node 130 may be arranged to perform receiver directed rate selection. Consequently, STA node 130 may need to select a data rate to communicate packets 164, 174 between STA node 130 and AP node 110 prior to communicating the packets 164, 174.

While the following detailed description references example implementations in relation to LDPC codes, the embodiments are not necessarily limited thereto and may be applied to other coding/decoding schemes where suitably appropriate.

LDPC codes are a form of error correction codes similar to Turbo codes, but much more computationally intensive with the advantage that they can achieve near Shannon-limit communication channel capacity. An LDPC code is a linear message encoding technique defined by a sparse parity check matrix. The message to be sent is encoded using a generator matrix or the sparse parity check matrix and when it reaches its destination, it is decoded using the sparse parity check matrix.

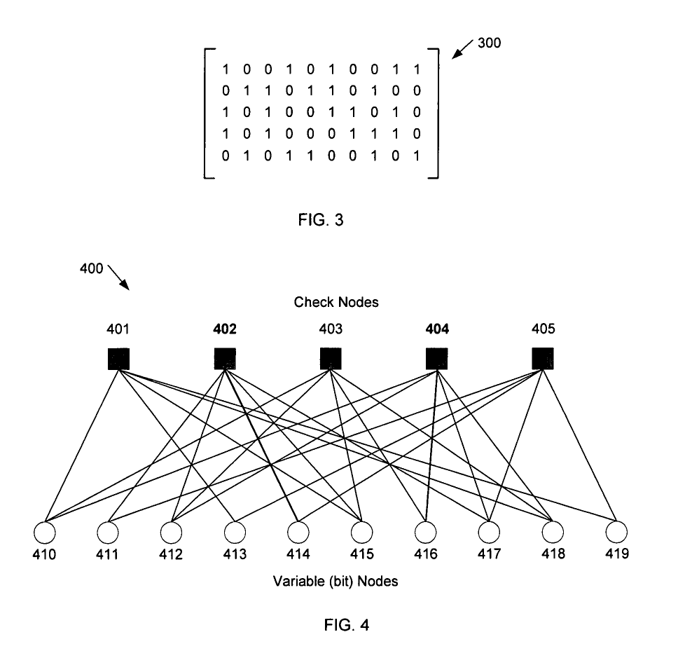

FIGS. 3 and 4 respectively, illustrate one embodiment of a parity check matrix 300 and one embodiment of a bipartite graph 400 associated with parity check matrix 300 showing the parity relationships of a 10-bit codeword. An LDPC decoding algorithm may be implemented as a series of computations derived from a message-passing iterative bipartite graph such as graph 400. In this example, variable nodes 410-419 (also called “bit nodes”) represent the bits in a codeword and check nodes 401-405 represent the parity relationships between those bits. The lines connecting check nodes 401-405 to variable nodes 410-419 are called “edges.” The number of check nodes 401-405 and bit nodes 410-419, as well as how they communicate, is defined by parity check matrix 300 (FIG. 3). The basic principle is to measure the probability of an encoded bit having a logic state of 0 or 1 based on the probable values of the other bits in the same word. A sequence of decoding iterations may be performed to either converge the probability value towards a bit value of zero or one. The bit and check nodes essentially perform a series of computations to reach a convergence on the likelihood about the logic state (for example using a set of bilinear transforms to converge a value toward zero or infinity). This operation is iterative and eventually after a series of iterations the likelihood ratio converges in one direction or the other.

LDPC encoder/decoder 206 may utilize a LDPC code to perform the FEC coding. In a general analysis, an (n, k) LDPC code has k information bits and n coded bits with code rate r=k/n. A parity check matrix H of dimension (n−k)×n may be developed that fully describes the LDPC code. One embodiment of the parity check matrix H definition provides low code density and therefore low complexity, while providing good performance in fading. In one embodiment, a parity check base matrix H may have 24 base columns for simplified decoding.

In one embodiment, a parity check base matrix may be defined for various code lengths n for a given code rate. The set of shifts in the base model matrix are used to determine the shift sizes for all other code lengths of the same code rate. For example, for a code rate of 5/6, a parity check base matrix comprising 24 columns, an expansion factor z may be defined as n/24 for code length n. For a code rate of 5/6, each code definition specifies a 24-column parity check base matrix H. Each entry in the parity check base matrix H specifies the amount of shift to be applied to a cyclically-shifted identity sub-matrix I_{Z×Z} that populates that location of parity check base matrix H. The identity sub-matrix I_{Z×Z} corresponding to a location of an entry in the parity check base matrix H may be cyclically-shifted laterally to the right or to the left in accordance with the corresponding value of the entry defined in the corresponding location in the parity check base matrix. In one embodiment, the identity sub-matrix I_{Z×Z} may be cyclically laterally shifted to the right by the value of the entry in the corresponding parity check base matrix H. For example, if the entry in parity check base matrix H_{1,1} is an integer n, then the identity sub-matrix I_{Z×Z} corresponding to the location H_{1,1} may be cyclically shifted laterally by n. It will be appreciated that each entry n in the parity check base matrix H will have a value that is less than z. A dash (-) in the location of parity check base matrix H indicates an all-zero sub-matrix I_{Z×Z}. Parity check base matrix H may then be expanded to the indicated block size using the appropriate expansion factor and indicated cyclic shifts.

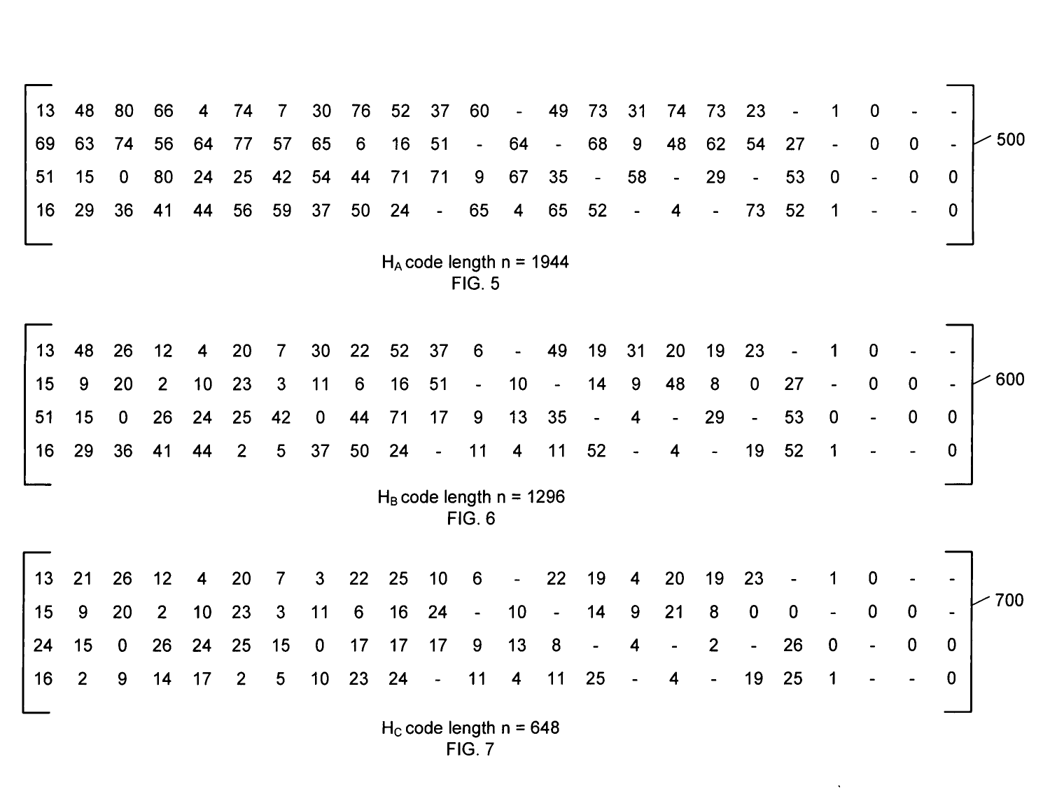

FIG. 5 illustrates one embodiment of a parity check base matrix H₁ 500 for a code rate 5/6 and code length n=1944. For a code rate of 5/6, each code definition specifies a 24-column parity check base matrix H_{A} 500. For code length n=1944, the expansion factor z= 1944/24=81. Therefore, each entry in the parity check base matrix H_{A} 500 specifies the amount of shift to be applied to an 81×81 cyclically-shifted identity sub-matrix I_{81×81} that populates the respective location of parity check base matrix H_{A} 500. A dash (-) in the location of parity check base matrix H_{A} 500 indicates an all-zero sub-matrix I_{81×81}. For example, entry H_{1,1} of parity check base matrix H_{A} is 13, therefore, the identity sub-matrix I_{81×81} associated with the respective location H_{1,1} is cyclically shifted laterally to the right by 13. It will be appreciated that each entry n in parity check base matrix H_{A} will have a value that is less than 81. Parity check base matrix H_{A} 500 may then be expanded to the indicated block size using the appropriate expansion factor and indicated cyclic shifts.

FIG. 6 illustrates one embodiment of a parity check base matrix H_{B} 600 for a code rate 5/6 and code length n=1296. For a code rate of 5/6, each code definition specifies a 24-column parity check base matrix H_{B} 600. For code length n=1296, the expansion factor z= 1296/24=54. Therefore, each entry in the parity check base matrix H_{B} 600 specifies the amount of shift to be applied to a 54×54 cyclically-shifted identity sub-matrix I_{54×54} that populates the respective location of parity check base matrix H_{B} 600. For example, entry H_{1,1} of parity check base matrix H_{B} is 13, therefore, the identity sub-matrix I_{54×54} associated with the respective location H_{1,1} is cyclically shifted laterally to the right by 13. A dash (-) in the location of parity check base matrix H_{B} 600 indicates an all-zero sub-matrix I_{54×54}. It will be appreciated that each entry m in parity check base matrix H_{A} will have a value that is less than 54. Parity check base matrix H_{B} 600 may then be expanded to the indicated block size using the appropriate expansion factor and indicated cyclic shifts.

FIG. 7 illustrates one embodiment of a parity check base matrix H_{C} 700 for a code rate 5/6 and code length n=648. For a code rate of 5/6, each code definition specifies a 24-column parity check base matrix H_{C} 700. For code length n=648, the expansion factor z= 648/24=27. Therefore, each entry in the parity check base matrix H_{C} 700 specifies the amount of shift to be applied to a 27×27 cyclically-shifted identity sub-matrix I_{27×27} that populates the respective location of parity check base matrix H_{C} 700. For example, entry H_{1,1} of parity check base matrix H_{C} is 13, therefore, the sub-identity sub-matrix I_{27×27} associated with the respective location H_{1,1} is cyclically shifted laterally to the right by 13. A dash (-) in the location of parity check base matrix H₃ 700 indicates an all-zero sub-matrix I_{27×27}. It will be appreciated that each entry m in parity check base matrix H_{A} will have a value that is less than 27. Base matrix H_{C} 700 may then be expanded to the indicated block size using the appropriate expansion factor and indicated cyclic shifts.

Operations for the above system and subsystem may be further described with reference to the following figures and accompanying examples. Some of the figures may include a logic flow. Although such figures presented herein may include a particular logic flow, it can be appreciated that the logic flow merely provides an example of how the general functionality described herein can be implemented. Further, the given logic flow does not necessarily have to be executed in the order presented unless otherwise indicated. In addition, the given logic flow may be implemented by a hardware element, a software element executed by a processor, or any combination thereof. The embodiments are not limited in this context.

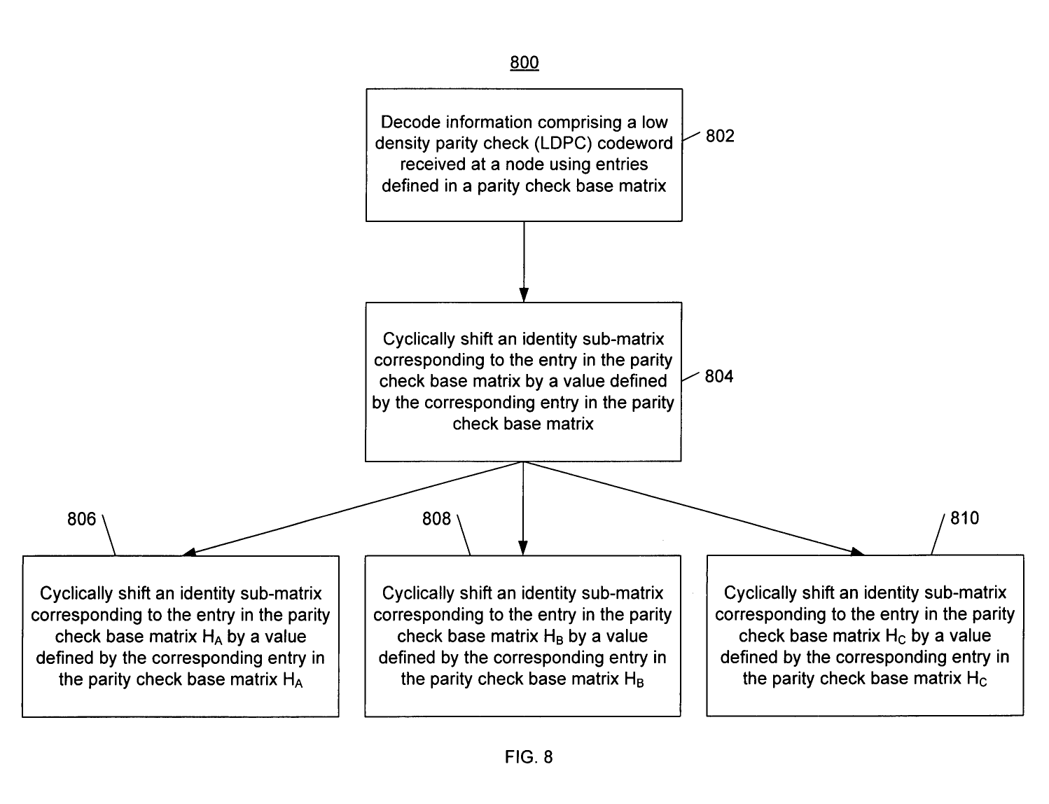

FIG. 8 illustrates one embodiment of a logic flow 800. Module 206 decodes (802) information comprising a low density parity check (LDPC) codeword received at node 110, 120 0r 130 using entries defined in a parity check base matrix H. Module 206 cyclically shifts (804) an identity sub-matrix I corresponding to the entry m in the parity check base matrix H by a value defined by the corresponding entry m in the parity check base matrix H. In one embodiment, identity sub-matrix I may be shifted laterally to the right. In one embodiment, the parity check base matrix H is defined based on a rate of 5/6. In one embodiment, the parity check base matrix comprises 24 columns and 4 rows. In one embodiment, the codeword has a length of 1944. In one embodiment, for a codeword length of 1944, parity check base matrix H, may be defined (806) in accordance with parity check base matrix H_{A} shown in FIG. 5. In one embodiment, for a codeword of 1296, parity check base matrix H, may be defined (808) in accordance with parity check base matrix H_{B} shown in FIG. 6. In one embodiment, for a codeword has a length of 648, parity check identity matrix H, may be defined (810) in accordance with parity check base matrix H_{C}.

Numerous specific details have been set forth herein to provide a thorough understanding of the embodiments. It will be understood by those skilled in the art, however, that the embodiments may be practiced without these specific details. In other instances, well-known operations, components and circuits have not been described in detail so as not to obscure the embodiments. It can be appreciated that the specific structural and functional details disclosed herein may be representative and do not necessarily limit the scope of the embodiments.

It is also worthy to note that any reference to “one embodiment” or “an embodiment” means that a particular feature, structure, or characteristic described in connection with the embodiment is included in at least one embodiment. The appearances of the phrase “in one embodiment” in various places in the specification are not necessarily all referring to the same embodiment.

Some embodiments may be implemented using an architecture that may vary in accordance with any number of factors, such as desired computational rate, power levels, heat tolerances, processing cycle budget, input data rates, output data rates, memory resources, data bus speeds and other performance constraints. For example, an embodiment may be implemented using software executed by a general-purpose or special-purpose processor. In another example, an embodiment may be implemented as dedicated hardware, such as a circuit, an application specific integrated circuit (ASIC), Programmable Logic Device (PLD) or digital signal processor (DSP), and so forth. In yet another example, an embodiment may be implemented by any combination of programmed general-purpose computer components and custom hardware components. The embodiments are not limited in this context.

Some embodiments may be described using the expression “coupled” and “connected” along with their derivatives. It should be understood that these terms are not intended as synonyms for each other. For example, some embodiments may be described using the term “connected” to indicate that two or more elements are in direct physical or electrical contact with each other. In another example, some embodiments may be described using the term “coupled” to indicate that two or more elements are in direct physical or electrical contact. The term “coupled,” however, also may mean that two or more elements are not in direct contact with each other, but yet still co-operate or interact with each other. The embodiments are not limited in this context.

Some embodiments may be implemented, for example, using a machine-readable medium or article which may store an instruction or a set of instructions that, if executed by a machine, may cause the machine to perform a method and/or operations in accordance with the embodiments. Such a machine may include, for example, any suitable processing platform, computing platform, computing device, processing device, computing system, processing system, computer, processor, or the like, and may be implemented using any suitable combination of hardware and/or software. The machine-readable medium or article may include, for example, any suitable type of memory module, such as the examples given with reference to FIG. 2. For example, the memory module may include any memory device, memory article, memory medium, storage device, storage article, storage medium and/or storage module, memory, removable or non-removable media, erasable or non-erasable media, writeable or re-writeable media, digital or analog media, hard disk, floppy disk, Compact Disk Read Only Memory (CD-ROM), Compact Disk Recordable (CD-R), Compact Disk Rewriteable (CD-RW), optical disk, magnetic media, various types of Digital Versatile Disk (DVD), a tape, a cassette, or the like. The instructions may include any suitable type of code, such as source code, compiled code, interpreted code, executable code, static code, dynamic code, and the like. The instructions may be implemented using any suitable high-level, low-level, object-oriented, visual, compiled and/or interpreted programming language, such as C, C++, Java, BASIC, Perl, Matlab, Pascal, Visual BASIC, assembly language, machine code, and so forth. The embodiments are not limited in this context.

While certain features of the embodiments have been illustrated as described herein, many modifications, substitutions, changes and equivalents will now occur to those skilled in the art. It is therefore to be understood that the appended claims are intended to cover all such modifications and changes as fall within the true spirit of the embodiments.

1. A method, comprising:
decoding information comprising a low density parity check (LDPC) codeword received at a node using entries defined in a parity check base matrix.

2. The method of claim 1, comprising:
cyclically shifting an identity sub-matrix corresponding to said entry in said parity check base matrix by a value defined by said corresponding entry in said parity check base matrix.

3. The method of claim 2, comprising:
right shifting said identity sub-matrix laterally to the right.

4. The method of claim 1, wherein said parity check base matrix is defined based on a rate of 5/6.

5. The method of claim 4, wherein said parity check base matrix comprises 24 columns and 4 rows.

6. The method of claim 5, wherein said codeword has a length of 1944.

7. The method of claim 6, wherein said entries in said parity check base matrix are defined in accordance with parity check base matrix H_{A}.

8. The method of claim 5, wherein said codeword has a length of 1296.

9. The method of claim 8, wherein said entries in said parity check base matrix are defined in accordance with parity check base matrix H_{B}.

10. The method of claim 5, wherein said codeword has a length of 648.

11. The method of claim 10, wherein said entries in said parity check base matrix are defined in accordance with parity check base matrix H_{C}.

12. An apparatus, comprising:
a decoder to decode information comprising a low density parity check (LDPC) codeword received at a node using entries defined in a parity check base matrix.

13. The apparatus of claim 12, wherein said decoder is to cyclically shift an identity sub-matrix corresponding to said entry in said parity check base matrix by a value defined by said corresponding entry in said parity check base matrix.

14. The apparatus of claim 13, wherein said decoder is to shift said identity sub-matrix in accordance with said entries defined in accordance with parity check base matrix H_{A}.

15. The apparatus of claim 13, wherein said decoder is to shift said identity sub-matrix in accordance with said entries defined in accordance with parity check base matrix H_{B}.

16. The apparatus of claim 13, wherein said decoder is to shift said identity sub-matrix in accordance with said entries defined in accordance with parity check base matrix H_{C}.

17. A system, comprising:
an antenna; and
a decoder coupled to said antenna to decode information comprising a low density parity check (LDPC) codeword received at a node using entries defined in a parity check base matrix.

18. The system of claim 17, wherein said decoder is to cyclically shift an identity sub-matrix corresponding to said entry in said parity check base matrix by a value defined by said corresponding entry in said parity check base matrix.

19. The system of claim 18, wherein said decoder is to shift said identity sub-matrix in accordance with said entries defined in accordance with parity check base matrix H_{A}.

20. The system of claim 18, wherein said decoder is to shift said identity sub-matrix in accordance with said entries defined in accordance with parity check base matrix H_{B}.

21. The system of claim 18, wherein said decoder is to shift said identity sub-matrix in accordance with said entries defined in accordance with parity check base matrix H_{C}.

22. An article comprising a machine-readable storage medium containing instructions that if executed enable a system to decode information comprising a low density parity check (LDPC) codeword received at a node using entries defined in a parity check base matrix.

23. The article of claim 22, comprising instructions that if executed enable the system to cyclically shift an identity sub-matrix corresponding to said entry in said parity check base matrix by a value defined by said corresponding entry in said parity check base matrix.

24. The article of claim 22, comprising instructions that if executed enable the system to define said entries in said parity check base matrix in accordance with parity check base matrix H_{A}.

25. The article of claim 22, comprising instructions that if executed enable the system to define said entries in said parity check base matrix in accordance with parity check base matrix H_{B}.

26. The article of claim 22, comprising instructions that if executed enable the system to define said entries in said parity check base matrix in accordance with parity check base matrix H_{C}.
